(19) United States
(12) Patent Application Publication
(10) Pub. No.: US 2023/0251521 A1
(43) Pub. Date: Aug. 10, 2023

(54) POLARIZER, DISPLAY PANEL AND MANUFACTURING METHOD THEREOF

(71) Applicant: HUIZHOU CHINA STAR OPTOELECTRONICS DISPLAY CO., LTD., Huizhou, Guangdong (CN)

(72) Inventors: Ding LI, Huizhou (CN); Gang YU, Huizhou (CN)

(21) Appl. No.: 17/608,157

(22) PCT Filed: Aug. 9, 2021
(86) PCT No.: PCT/CN2021/111434

§ 371 Date: Nov. 2, 2021

(30) Foreign Application Priority Data
Feb. 10, 2021 (CN) 202110185235.2

(51) Int. Cl. G02F 1/1335; H10K 50/80

(52) U.S. Cl. CPC G02F 1/133531; H10K 50/868

(57) ABSTRACT

A polarizer, a display panel and a manufacturing method thereof are provided. The display panel includes a cell, a liquid crystal layer and a polarizer. The polarizer includes a polarizing layer and a first glass substrate. The first glass substrate is employed as a protective layer for the polarizing layer, and possesses functions of isolating water vapor, preventing water vapor from damaging the polarizer, thereby avoiding display defects such as light leakage or uneven display of the display panel.

### FIELD OF THE INVENTION

The present invention relates to a display field, and more particularly to a polarizer, a display panel and a manufacturing method thereof.

### BACKGROUND OF THE INVENTION

A polarizer used in display devices, such as Liquid Crystal Display (LCD) and Organic Light Emitting Diode (OLED) usually has a multi-functional layer structure as shown in FIG. 1. FIG. 1 is a structure diagram of a polarizer according to the prior art. The polarizer 10 includes a polarizing layer 11 with a polarization function, and the material of the polarizing layer 11 may be a polyvinyl alcohol film layer (Polyvinyl Alcohol, PVA), etc.; a first protective layer 12 and a second protective layer 13 attached to two opposite surfaces of the polarizing layer 11, and the material of the first protective layer 12 and the second protective layer 13 may be resin films, such as Tri-cellulose Acetate (Tri-cellulose Acetate, TAC), Polyethylene Glycol Terephthalate (PET) and Acrylic resin (Polymeric Methyl Methacrylate, PMMA). However, the aforementioned resin films have poor humidity and heat resistance, and the polarizer is prone to deformation in a humid and hot environment, resulting in poor display.

### SUMMARY OF THE INVENTION

In order to solve the above problems, the present application provides a polarizer, a display panel and a manufacturing method thereof to avoid poor display caused by the deformation of the polarizer in a humid and hot environment.

The present application provides a manufacturing method of a display panel, including steps of:

oppositely arranging a first substrate and a second substrate for cell, and injecting liquid crystal between the first substrate and the second substrate to form a cell;

providing a first glass substrate, and preparing a polarizing layer on one side of the first glass substrate to form a polarizer;

laminating the polarizer to a side of the first substrate and/or the second substrate away from the liquid crystal layer, wherein the polarizing layer is disposed between the first substrate and/or the second substrate and the first glass substrate.

In some embodiments, the step of forming the polarizer further includes:

laminating a second glass substrate to a side of the polarizing layer away from the first glass substrate to form the polarizer.

In some embodiments, the step of laminating the polarizer to the side of the first substrate and/or the second substrate away from the liquid crystal layer further includes:

laminating a pressure-sensitive adhesive layer on a side of the second glass substrate away from the polarizing layer;

laminating the side of the second glass substrate laminated by the pressure-sensitive adhesive layer with the side of the first substrate and/or the second substrate away from the liquid crystal.

In some embodiments, the step of preparing the polarizing layer includes:

forming an alignment layer on the one side of the first glass substrate;

attaching polarizing material to the alignment layer to form the polarizing layer.

In some embodiments, a method for forming the alignment layer includes any one of rubbing alignment, photo alignment or stretching alignment.

In some embodiments, the step of attaching the polarizing material includes:

immersing the first glass substrate with the alignment layer formed on the side in a solution containing the polarizing material to attach the polarizing material to a surface of the alignment layer.

In some embodiments, the step of attaching the polarizing material includes:

printing the polarizing material on a side of the alignment layer away from the first glass substrate to attach the polarizing material to a surface of the alignment layer.

In some embodiments, the step of preparing the polarizing layer includes: forming an alignment layer by stretching alignment, and immersing the alignment layer in a solution containing polarizing material to attach the polarizing material to the alignment layer, and laminating the alignment layer attached with the polarizing material to a side of the first glass substrate.

In some embodiments, the polarizing material is cured after attaching the polarizing material to the alignment layer.

The present application further provides a display panel, including:

a cell, the cell includes a first substrate and a second substrate oppositely arranged with the first substrate for cell, and a liquid crystal layer arranged between the first substrate and the second substrate;

a polarizer, arranged with a side of the first substrate and/or the second substrate away from the liquid crystal layer;

wherein the polarizer includes a polarizing layer and a first glass substrate, and the polarizing layer is arranged on a side of the first substrate and/or the second substrate away from the liquid crystal layer, and the first glass substrate is arranged on a side of the polarizing layer away from the cell.

In some embodiments, the polarizer further includes a second glass substrate, and the second glass substrate is disposed between the polarizing layer and the cell.

In some embodiments, a functional layer is further attached to a side of the first glass substrate away from the cell.

In some embodiments, the functional layer is one or more of a low-reflection functional layer, a hardening functional layer, an anti-glare functional layer, an anti-static functional layer and an anti-fingerprint functional layer.

The present application further provides a display panel, including an OLED light-emitting structure and a polarizer arranged on one side of the OLED light-emitting structure, wherein the polarizer includes a first glass substrate, a second glass substrate and a polarizing layer, and the polarizing layer is disposed between the first glass substrate and the second glass substrate.

In some embodiments, a photochromic layer is provided on a side of the first glass substrate or the second glass substrate away from the polarizing layer.

The present application further provides a polarizer, including:

a first glass substrate, the first glass substrate has a first side;

a polarizing layer, the polarizing layer possesses a polarization function and is disposed on the first side.

In some embodiments, the polarizer further includes an outer protective layer, and the polarizing layer is disposed between the first glass substrate and the outer protective layer.

In some embodiments, the polarizer further includes a pressure-sensitive adhesive layer arranged on a side of the outer protective layer away from the polarizing layer.

In some embodiments, the polarizer further includes a release film layer, and the release film layer is arranged on a side of the pressure-sensitive adhesive layer away from the outer protective layer.

In some embodiments, the outer protective layer is a glass substrate.

The present application provides a display panel, including a cell and polarizer on both sides of the cell. The polarizer includes a polarizing layer with a polarization function and a first glass substrate. The first glass substrate is employed as a protective layer for the polarizing layer, and possesses functions of isolating water vapor, preventing water vapor from damaging the polarizer, thereby avoiding display defects such as light leakage or uneven display of the display panel.

The present application further provides a manufacturing method of a display panel. The polarizing layer with the polarization function is formed on a side of the first glass substrate, and the side of the polarizing layer away from the first glass substrate is attached to the cell to solve the adverse effects of high temperature and squeezing operations on the cell in the process of forming the polarizing layer in the prior art, and to improve the production yield and reliability of display products.

### BRIEF DESCRIPTION OF THE DRAWINGS

In order to more clearly illustrate the embodiments of the present application, the following figures will be described in the embodiments are briefly introduced. It is obvious that the drawings are only some embodiments of the present application, those of ordinary skill in this field can obtain other figures according to these figures without paying the premise.

FIG. 1 is a structure diagram of a polarizer according to the prior art.

FIG. 2 is a cross-sectional structure diagram of a display panel provided by an embodiment of the present application.

FIG. 3 is a flowchart of a manufacturing method of a display panel provided by an embodiment of the present application.

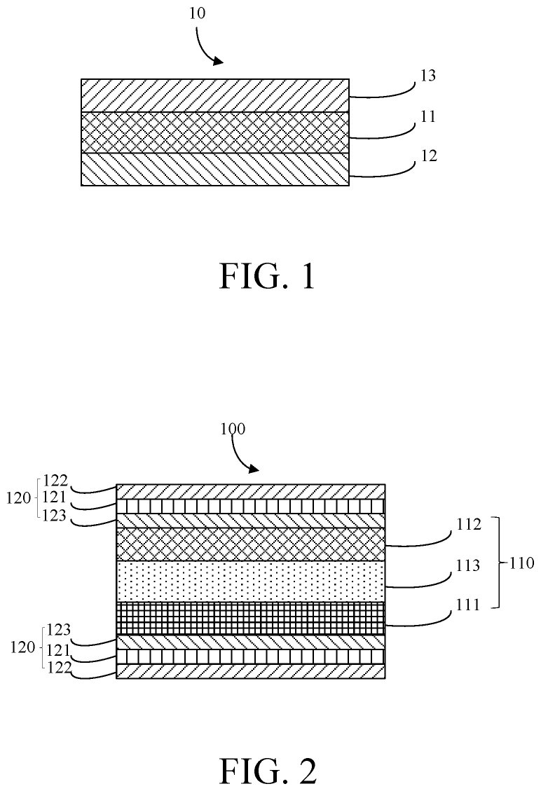

### DETAILED DESCRIPTION OF PREFERRED EMBODIMENTS

The embodiments of the present application are described in detail below, and the examples of the embodiments are illustrated in the drawings, wherein the same or similar reference numerals are used to refer to the same or similar components or components having the same or similar functions. The terms “first”, “second”, “third”, etc. (if present) in the specification and claims of the present application and the foregoing figures are used to distinguish similar objects, and are not necessary used to describe for a particular order or sequence. It should be understood that the objects so described are interchangeable as appropriate. In the description of the present application, “plurality” means two or more unless with being specifically indicated otherwise. Furthermore, the terms “including” and “having” and their any deformations are intended to cover non-exclusive inclusion.

The polarizer is an important part of the display panel, which can control the polarization direction of the transmitted light. The humidity and heat resistance of the polarizer has an important influence on the display performance of the display panel. However, the protective layer of the polarizer in the prior art generally has poor humidity and heat resistance, and water vapor is likely to damage the polarizer, causing display defects such as light leakage or uneven display of the display panel.

Please refer to FIG. 2. FIG. 2 is a cross-sectional structure diagram of a display panel 100 provided by an embodiment of the present application. The display panel 100 includes:

a liquid crystal cell 110, the liquid crystal cell 110 includes a first substrate 111, a second substrate 112 arranged in a cell with the first substrate 111, and a liquid crystal layer 113 arranged between the first substrate 111 and the second substrate 112. In this embodiment, the first substrate 111 may be an array substrate, and the second substrate 112 may be a color filter substrate. The present application does not limit the types of array substrates and color filter substrates. In other embodiments of the present application, the array substrate and the color filter substrate may be COA (Color Filter On Array) type array substrate and color filter substrate.

A polarizer 120 is provided. The polarizer 120 is arranged with a side of the first substrate 111 and/or the second substrate 112 away from the liquid crystal layer 113. In some embodiments, the polarizer 120 may be arranged only with one side of the first substrate 111 or the second substrate 112 away from the liquid crystal layer 113. In some other embodiments, the polarizer 120 may be respectively arranged with one side of the first substrate 111 and one side of the second substrate 112 away from the liquid crystal layer 113.

The polarizer 120 includes a polarizing layer 121 and a first glass substrate 122, and the polarizing layer 121 is arranged on a side of the first substrate 111 and/or the second substrate 112 away from the liquid crystal layer 113, and the first glass substrate 122 is arranged on a side of the polarizing layer 121 away from the cell 110.

The polarizing layer 121 is a functional layer in the polarizer 120 for polarizing light. The polarizing layer 121 may be a material with a polarization function in the prior art, such as iodine, iodine compounds, dichroic dyes, etc., and the present application has no limitation herein.

The first glass substrate 122 is flexible glass. The flexible glass is employed as a protective layer for the polarizing layer 121, and possesses functions of isolating water vapor, preventing water vapor from damaging the polarizer 120, thereby avoiding display defects such as light leakage or uneven display of the display panel 100.

Besides, in the embodiment of the present application, the polarizer 120 may be directly laminated to the side of the first substrate 111 and/or the second substrate 112 away from the liquid crystal layer 113. The first substrate 111 and/or the second substrate 112 may also act to protect the polarizing layer, for saving process materials and manufacturing processes, and meanwhile reducing the thickness of the display panel 100, which is conducive to achieving a lighter and thinner display product.

In some embodiments, the polarizer 120 further includes a second glass substrate 123, and the second glass substrate 123 is disposed between the polarizing layer 121 and the cell 110. A second glass substrate 123 may be further arranged between the first glass substrate 111 and/or the second glass substrate 112 and the polarizing layer 121 to further protect the polarizing layer 121 for enhancing the humidity and heat resistance of the polarizer 120, and thus to improve the reliability and durability of the display panel 100 and to extend the service life of the display product.

The display panel 100 of the embodiment of the present application is a liquid crystal display panel. The present application does not limit the type of the liquid crystal display panel. It may be a vertical electric field type liquid crystal display panel, such as a twisted nematic (TN) type liquid crystal display panel, a multi-domain ertical alignment (MVA) type liquid crystal display panel, and can also be a horizontal electric field type liquid crystal display panel, such as a fringe field switching (FFS) type liquid crystal display panel or an in-plane switching (IPS) liquid crystal display panel. The present application provides a display panel 100, including a cell 110 and polarizer 120 on both sides of the cell 110. The polarizer 120 includes a polarizing layer 121 with a polarization function and a first glass substrate 122. The first glass substrate 122 is employed as a protective layer for the polarizing layer 121, and possesses functions of isolating water vapor, preventing water vapor from damaging the polarizer 120, thereby avoiding display defects such as light leakage or uneven display of the display panel 100.

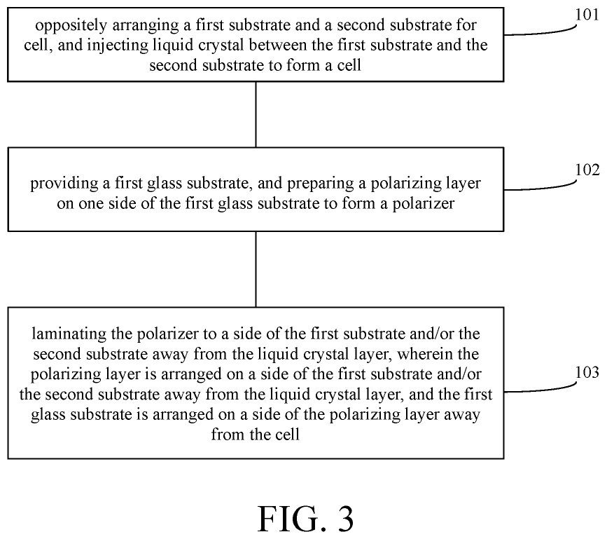

Please refer to FIG. 3. FIG. 3 is a flowchart of a manufacturing method of a display panel 100 provided by an embodiment of the present application. The manufacturing method of a display panel 100, including steps of:

Step 101: oppositely arranging a first substrate 111 and a second substrate 112 for cell, and injecting liquid crystal between the first substrate 111 and the second substrate 112 to form a cell 110.

The first substrate 111 is an array substrate, and the second substrate 112 is a color filter substrate. The filler is coated between the first substrate 111 and the second substrate 112, and the filler is located in the seal area, and then the cell process is accomplished with the first substrate 111 and the second substrate 112. Liquid crystal is injected between the first substrate 111 and the second substrate 112 to form a liquid crystal layer 113. The liquid crystal may be one or more of nematic, smectic, cholesteric and blue phase liquid crystals.

Step 102: providing a first glass substrate 122, and preparing a polarizing layer 121 on one side of the first glass substrate 122 to form a polarizer 120.

The first glass substrate 122 is flexible glass. The flexible glass is employed as a protective layer for the polarizing layer 121, and possesses functions of isolating water vapor. The polarizing layer 121 is a functional layer in the polarizer 120 for polarizing light. The polarizing layer 121 may be a material with a polarization function in the prior art, such as iodine, iodine compounds, dichroic dyes, etc., and the iodine molecules or long chains of iodide ions are arranged on the first glass substrate 122 in an orderly manner. It can absorb the electric field component of the beam parallel to its arrangement direction, and only allow the electric field component of the beam in the vertical direction pass through, which possesses a good polarization function. The dichroic dyes may be anthraquinone dyes and polyazo dyes, and these dyes possess good humidity and heat resistance and excellent stability. Certainly, in some embodiments, the polarizing material can also be other materials with a polarizing function, and the present application has no limitation here.

Step 103: laminating the polarizer 120 to a side of the first substrate 111 and/or the second substrate 112 away from the liquid crystal layer 113, wherein the polarizing layer 121 is arranged on a side of the first substrate 111 and/or the second substrate 112 away from the liquid crystal layer 113, and the first glass substrate 122 is arranged on a side of the polarizing layer 121 away from the cell 110.

The polarizer 120 is laminated to the cell 110. Specifically, the polarizing layer 121 is laminated to the side of the first substrate 111 and/or the second substrate 112 away from the liquid crystal layer 113. The first substrate 111 and/or the second substrate 112 may also be the protective layer of the polarizing layer, preventing the damage of the water vapor to the polarizer 120.

In the manufacturing method of the embodiment of the present application, the polarizing layer 121 for polarizing light is first prepared on the first glass substrate 122, and then laminated to the liquid crystal cell 110 to prevent the adverse effects of high temperature and squeezing operations on the cell 110 in the process of forming the polarizing layer 121 in the prior art, and to improve the production yield and reliability of display products.

In some embodiments, the step of forming the polarizer 120 further includes:

laminating a second glass substrate 123 to a side of the polarizing layer 121 away from the first glass substrate 122 to form the polarizer 120.

The first glass substrate 122 and the second glass substrate 123 are respectively attached to two opposite surfaces of the polarizing layer 121 to protect the polarizing layer 121 in advance to increase the humidity and heat resistance of the polarizer 120.

In some embodiments, the step of laminating the polarizer 120 to the side of the first substrate 111 and/or the second substrate 112 away from the liquid crystal layer 113 includes:

laminating a pressure-sensitive adhesive layer on a side of the second glass substrate 123 away from the polarizing layer 121.

The side of the second glass substrate 123 with the pressure-sensitive adhesive layer is laminated with the side of the first substrate 111 and/or the second substrate 112 away from the liquid crystal layer 113.

The pressure-sensitive adhesive layer is used to bond the polarizer 120 to the first substrate 111 and/or the second substrate 112. The pressure-sensitive adhesive layer may be any suitable pressure-sensitive adhesive, and may be a solvent-based pressure-sensitive adhesive, a non-aqueous emulsion-type pressure-sensitive adhesive, and the like. In one embodiment, the pressure-sensitive adhesive layer may be an acrylic polymer. As long as the pressure-sensitive adhesive layer possesses suitable wettability, adhesiveness, excellent optical transparency and water and heat resistance for achieving the purpose of the present application, and there is no limitation here.

In some embodiments, the step of preparing the polarizing layer 121 includes:

forming an alignment layer on the one side of the first glass substrate 122, and attaching polarizing material to the alignment layer to form the polarizing layer 121.

An alignment treatment is performed on one side of the first glass substrate 122, and then a polarizing material is attached to the side after the alignment treatment, and the polarizing material is regularly adsorbed and arranged on the side to form a polarizing layer 121 with a polarization function.

In some embodiments, a method for forming the alignment layer includes any one of rubbing alignment, photo alignment or stretching alignment.

The rubbing alignment can be oriented rubbing on the side with a roller brush to form alignment grooves, and the polarizing material is adsorbed in the alignment grooves to achieve an orderly arrangement.

The photo-alignment can be irradiated with ultraviolet light on the high-molecular polymer with a photosensitizer on the side, so that the high-molecular polymer has alignment ability, and the polarizing material is arranged in an orderly manner along the direction in which the high-molecular polymer is arranged.

The stretching alignment can be a resin film after orientated stretching treatment to be laminated on the side. The resin film can be a PVA film. The main components of the PVA film are light atoms, such as hydrocarbons, which possess high transparency and high ductility. It also possesses the properties of good polarizing material adsorption and film-forming characteristics, which is the core raw material of the polarizer. After the oriented stretching treatment, the molecules in the resin film are aligned, and the attached polarizing material will also be ordered in accordance with the direction of the molecules in the resin film.

In some embodiments, the step of attaching the polarizing material includes: immersing the first glass substrate with the alignment layer formed on the side in a solution containing the polarizing material to attach the polarizing material to a surface of the alignment layer.

In some embodiments, the polarizing material is printed on a side of the alignment layer away from the first glass substrate 122 to attach the polarizing material to a surface of the alignment layer.

The polarizing material is arranged in an orderly manner on the surface of the alignment layer to form a polarizing layer 121 for polarizing light. The polarizing material may iodine, iodine compounds, dichroic dyes, etc., and the iodine molecules or long chains of iodide ions are arranged on the first glass substrate 122 in an orderly manner. It can absorb the electric field component of the beam parallel to its arrangement direction, and only allow the electric field component of the beam in the vertical direction pass through, which possesses a good polarization function. The dichroic dyes may be anthraquinone dyes and polyazo dyes, and these dyes possess good humidity and heat resistance and excellent stability. Certainly, in some embodiments, the polarizing material can also be other materials with a polarizing function, and the present application has no limitation here.

In some embodiments, the step of preparing the polarizing layer may include: forming an alignment layer by stretching alignment, and immersing the alignment layer in a solution containing polarizing material to attach the polarizing material to the alignment layer, and laminating the alignment layer attached with the polarizing material to a side of the first glass substrate.

In some embodiments, the attached polarizing material is cured after attaching the polarizing material to the alignment layer.

The curing treatment may be thermal curing, and the temperature of thermal curing may be 23° C. to 90° C., such as 25° C., 45° C., 60° C., 75° C. and 80° C. In this embodiment, by thermal curing to the polarizing material, the adhesion between the polarizing material and the alignment layer can be enhanced, and the reliability of the polarizer 120 can be improved.

In some embodiments, a functional layer is further attached to a side of the first glass substrate 122 away from the cell 110. The functional layer may be one or more of a low-reflection functional layer, a hardening functional layer, an anti-glare functional layer, an anti-static functional layer and an anti-fingerprint functional layer.

The present application provides a manufacturing method of a display panel. The polarizing layer 121 with the polarization function is formed on a side of the first glass substrate 122, and the side of the polarizing layer 121 away from the first glass substrate 122 is attached to the cell 110 to solve the adverse effects of high temperature and squeezing operations on the cell in the process of forming the polarizing layer in the prior art, and to improve the production yield and reliability of display products.

The embodiment of the present application further provides a display panel, including an OLED light-emitting structure and a polarizer arranged on one side of the OLED light-emitting structure, wherein the polarizer includes a first glass substrate, a second glass substrate and a polarizing layer, and the polarizing layer is disposed between the first glass substrate and the second glass substrate.

In some embodiments, the side of the first glass substrate or the second glass substrate away from the polarizing layer is further arranged with a 1/4λ functional compensation film, such as a 1/4λ wave plate, to form a circular polarizer, which can reduce reflection of a metal electrode.

In some embodiments, a photochromic layer is provided on a side of the first glass substrate or the second glass substrate away from the polarizing layer to improve the contrast of the corresponding display products in outdoor sunlight.

In this embodiment, the display panel can be active or passive. The polarizer is arranged on one side of the OLED light-emitting structure. The OLED light-emitting structure can include an anode, a cathode, a hole injection layer, a hole transport layer, an electron transport layer, an electron injection layer and so on. For details, please refer to the prior art, which will not be repeated in the present application.

The embodiment of the present application further provides a polarizer, including: a first glass substrate, the first glass substrate has a first side; a polarizing layer, the polarizing layer possesses a polarization function and is disposed on the first side. It should be noted that, in this embodiment, the first side may be a side surface laminated to the cell in the liquid crystal display panel, or a side surface laminated to the light-emitting structure in the OLED display panel. The protective layer for the polarizing layer is flexible glass, and the flexible glass possesses a strong ability to isolate water vapor, effectively preventing water vapor from damaging the polarizer, thereby avoiding display defects such as light leakage or uneven display of the display panel.

In some embodiments, an outer protective layer is further arranged on the side of the polarizing layer away from the first glass substrate. In some embodiments, the outer protective layer may be the second glass substrate. The flexible glasses are attached to both two sides of the polarizing layer to protect the polarizing layer in advance to increase the humidity and heat resistance of the polarizer.

In some embodiments, a pressure-sensitive adhesive layer is further attached on a side of the outer protective layer away from the polarizing layer for laminating the polarizer to the cell or to the light-emitting panel of the OLED display device.

In some embodiments, a release film layer is further attached on a side of the pressure-sensitive adhesive layer away from the polarizing layer to prevent the pressure-sensitive adhesive layer from being contaminated before the polarizer is attached to the cell or the light-emitting panel of the OLED display device, which is beneficial to the mass production and storage of the polarizers.

The polarizer provided by the embodiment of the present application includes a first glass substrate and a polarizing ayer on one side of the first glass substrate. The first glass substrate can protect the polarizing layer, thereby improving the humidity and heat resistance of the polarizer. The polarizer of the embodiment of the present application can not only be applied to liquid crystal display panels and OLED display panels, but also can be used for sunglasses, anti-glare goggles, filters of photographic equipments, anti-glare treatment and light quantity adjustment of automobile headlights.

The polarizer, the display panel and the manufacturing method thereof provided by the embodiments of the present application are described in detail as aforementioned, and the principles and implementations of the present application have been described with reference to specific illustrations. The description of the foregoing embodiments is merely for helping to understand the technical solutions of the present application and the core ideas thereof; meanwhile, those skilled in the art will be able to change the specific embodiments and the scope of the application according to the idea of the present application. In conclusion, the content of the specification should not be construed as limiting the present application.

1. A manufacturing method of a display panel, including steps of:
oppositely arranging a first substrate and a second substrate for cell, and injecting liquid crystal between the first substrate and the second substrate to form a cell;
providing a first glass substrate, and preparing a polarizing layer on one side of the first glass substrate to form a polarizer;
laminating the polarizer to a side of the first substrate or the second substrate away from the liquid crystal layer, wherein the polarizing layer is disposed between the first substrate or the second substrate and the first glass substrate.

2. The manufacturing method according to claim 1, wherein the step of forming the polarizer further includes:
laminating a second glass substrate to a side of the polarizing layer away from the first glass substrate to form the polarizer.

3. The manufacturing method according to claim 2, wherein the step of laminating the polarizer to the side of the first substrate and/or the second substrate away from the liquid crystal further includes:
laminating a pressure-sensitive adhesive layer on a side of the second glass substrate away from the polarizing layer;
laminating the side of the second glass substrate laminated by the pressure-sensitive adhesive layer with the side of the first substrate and/or the second substrate away from the liquid crystal.

4. The manufacturing method according to claim 1, wherein the step of preparing the polarizing layer includes:
forming an alignment layer on the one side of the first glass substrate;
attaching polarizing material to the alignment layer to form the polarizing layer.

5. The manufacturing method according to claim 4, wherein a method for forming the alignment layer includes one of rubbing alignment, photo alignment or stretching alignment.

6. The manufacturing method according to claim 4, wherein the step of attaching the polarizing material includes:
immersing the first glass substrate with the alignment layer formed on the side in a solution containing the polarizing material to attach the polarizing material to a surface of the alignment layer.

7. The manufacturing method according to claim 4, wherein the step of attaching the polarizing material includes:
printing the polarizing material on a side of the alignment layer away from the first glass substrate to attach the polarizing material to a surface of the alignment layer.

8. The manufacturing method according to claim 1, wherein the step of preparing the polarizing layer includes: forming an alignment layer by stretching alignment, and immersing the alignment layer in a solution containing polarizing material to attach the polarizing material to the alignment layer, and laminating the alignment layer attached with the polarizing material to a side of the first glass substrate.

9. The manufacturing method according to claim 4, wherein the polarizing material is cured after attaching the polarizing material to the alignment layer.

10. A display panel, comprising:
a cell, wherein the cell includes a first substrate and a second substrate oppositely arranged with the first substrate, and a liquid crystal layer arranged between the first substrate and the second substrate; and
a polarizer arranged with a side of the first substrate or the second substrate away from the liquid crystal layer;
wherein the polarizer includes a polarizing layer and a first glass substrate, and the polarizing layer is arranged on a side of the first substrate or the second substrate away from the liquid crystal layer, and the first glass substrate is arranged on a side of the polarizing layer away from the cell.

11. The display panel according to claim 10, wherein the polarizer further includes a second glass substrate, and the second glass substrate is disposed between the polarizing layer and the cell.

12. The display panel according to claim 10, wherein a functional layer is further attached to a side of the first glass substrate away from the cell.

13. The display panel according to claim 12, wherein the functional layer is one or more of a low-reflection functional layer, a hardening functional layer, an anti-glare functional layer, an anti-static functional layer or an anti-fingerprint functional layer.

14. (canceled)

15. (canceled)

16. A polarizer, including:
a first glass substrate, the first glass substrate has a first side;
a polarizing layer, the polarizing layer possesses a polarization function and is disposed on the first side.

17. The polarizer according to claim 16, wherein the polarizer further includes an outer protective layer, and the polarizing layer is disposed between the first glass substrate and the outer protective layer.

18. The polarizer according to claim 17, wherein the polarizer further includes a pressure-sensitive adhesive layer arranged on a side of the outer protective layer away from the polarizing layer.

19. The polarizer according to claim 18, wherein the polarizer further includes a release film layer, and the release film layer is arranged on a side of the pressure-sensitive adhesive layer away from the outer protective layer.

20. The polarizer according to claim 16, wherein the outer protective layer is a glass substrate.
